(19) United States
(12) Patent Application Publication
(10) Pub. No.: US 2010/0096621 A1
(43) Pub. Date: Apr. 22, 2010

(54) ORGANIC TRANSISTOR AND MANUFACTURE METHOD THEREOF

(76) Inventor: Takashi Chuman, Saitama (JP)

Correspondence Address: WENDEROTH, LIND & PONACK, L.L.P., 1030 15th Street, N.W.,, Suite 400 East, Washington, DC, 20005-1503, US

(21) Appl. No.: 12/450,367

(22) PCT Filed: Mar. 23, 2007
(86) PCT No.: PCT/JP2007/055965

§ 371 Date: Oct. 28, 2009

(51) Int. Cl. H01L 51/10; H01L 51/40

(52) U.S. Cl. 257/40; 257/57; 438/99; 438/158; 257/E51.006

(57) ABSTRACT

[PROBLEMS] To provide an organic transistor in which high-resolution patterning can be performed, favorable contact can be achieved, and a leakage current can be prevented.

[SOLVING MEANS] An organic transistor includes a substrate 1, a gate electrode 2 formed on the substrate 1, a gate insulating layer formed on the gate electrode 2, a source electrode 4 and a drain electrode 5 formed on the gate insulating layer 3, an organic semiconductor layer 6 provided between the source electrode 2 and the drain electrode 3 and opposite to the gate electrode 2 with the gate insulating layer 3 interposed between them, and an insulating layer 7 having an opening portion 7a which defines the area where the organic semiconductor layer 6 is formed. The organic semiconductor layer 6 is formed through evaporation by using a low-molecular organic semiconductor material such as pentacen.

### TECHNICAL FIELD

The present invention relates to an organic transistor and a manufacture method thereof.

### BACKGROUND ART

Low-molecular organic semiconductors represented by pentacen are widely known as organic semiconductor materials having high mobility. The mobility thereof is up to 10 cm²/Vs and is significantly larger than that of amorphous silicon. Such low-molecular organic semiconductor materials are generally difficult to dissolve and thus are typically deposited by using a vacuum evaporation method. In the deposition, the organic semiconductor material is divided to form individual organic TFTs (Thin Film Transistor). Shadow masks have conventionally been used for patterning thereof. The shadow mask, however, has difficulty in providing high-resolution patterns and results in organic TFTs with a large pitch of several tens to several hundreds of micrometers. There is also a problem of positioning accuracy arising from the processing accuracy of the mask.

Organic Light Emitting Transistors (OLET) suffer from similar problems. The organic light emitting transistor is a combination of an organic electroluminescence (EL) element and an organic transistor with the aim of providing organic display devices. The organic light emitting transistor using a vertical-type organic transistor has drawn attention because of the transistor performance and the effectiveness of a light-emitting surface. The vertical-type organic light emitting transistor includes an organic semiconductor layer and an organic light emitting layer stacked vertically between a source electrode and a drain electrode. When a low-molecular organic material is used, the organic semiconductor layer and the organic light emitting layer are formed through evaporation using a shadow mask to present a problem of difficulty in achieving a higher-resolution pattern.

Patent Document 1 has proposed a structure in which a source electrode, a drain electrode, and a resist layer lying thereon and having the same shape as that of the electrodes are used as a patterning mask for an organic semiconductor in order to perform fine patterning of a low-molecular organic semiconductor layer.

[Patent Document 1] Japanese Patent Laid-Open No. 2006-93656

### DISCLOSURE OF THE INVENTION

### [Problems to be Solved by the Invention]

In this manner, the difficulty of higher-resolution patterning is an exemplary problem in forming the low-molecular organic semiconductor layer through evaporation. In placing a plurality of organic transistors, another exemplary problem is occurrence of a leakage current due to contact between organic semiconductor layers of adjacent organic transistors if the semiconductor layers of the individual organic transistors are not divided clearly.

In the structure described in Patent Document 1, the source electrode, the drain electrode, and the resist layer formed on the electrodes and having the same shape as that of the source and drain electrodes are used as the patterning mask, and the thickness of the source and drain electrodes is combined with the thickness of the resist layer lying thereon to increase the step height, thereby avoiding formation of an organic semiconductor layer on a side portion of the step. This causes the problem in that the source and drain electrodes are very thick to require a long time for the process and a large amount of material. In addition, the edge effect near the source and drain electrodes produced in the evaporation reduces the thickness of the organic semiconductor layer formed in a channel region to raise the possibility of failing to make favorable contact with the source and drain electrodes. Furthermore, since the source and drain electrodes are not present in a width direction of the channel region, it is difficult to control the area where the organic semiconductor is deposited. For example, when elements are placed in parallel on the same gate electrode, the problem is that the organic semiconductor layers of the adjacent elements may be connected to each other to cause a leakage current.

It is thus an object of the present invention to provide an organic transistor in which high-resolution patterning can be performed, favorable contact can be achieved, and a leakage current can be prevented, and a manufacture method thereof.

### [Means for Solving the Problems]

As described in claim 1, the present invention provides an organic transistor including, over a substrate, a gate electrode, a gate insulating layer, a source electrode and a drain electrode, and an organic semiconductor layer present between the source electrode and the drain electrode and made of a low-molecular organic semiconductor material, wherein an insulating layer is provided over a surface on which the organic semiconductor layer is formed through evaporation, the insulating layer having an opening portion which defines the area where the organic semiconductor layer is formed.

As described in claim 9, the present invention provides a method of manufacturing an organic transistor including, over a substrate, a gate electrode, a gate insulating layer, a source electrode and a drain electrode, and an organic semiconductor layer present between the source electrode and the drain electrode, wherein an insulating layer is provided over a surface on which the organic semiconductor layer is formed, the insulating layer having an opening portion which defines the area where the organic semiconductor layer is formed, and the insulating layer is used as a patterning mask to evaporate a low-molecular organic semiconductor material to form the organic semiconductor layer.

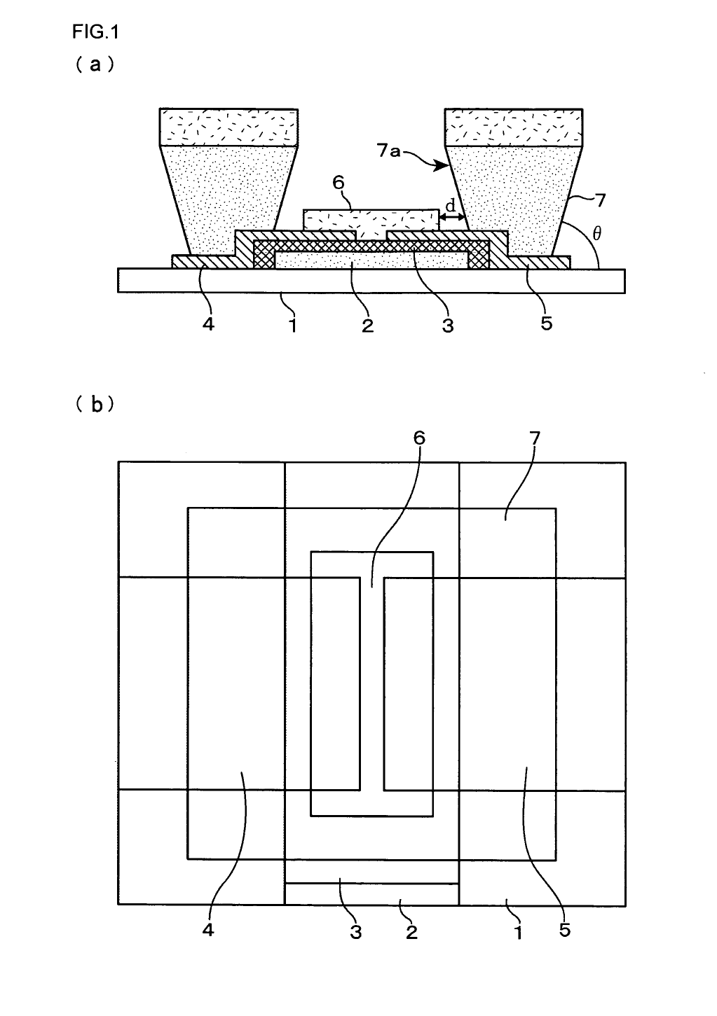

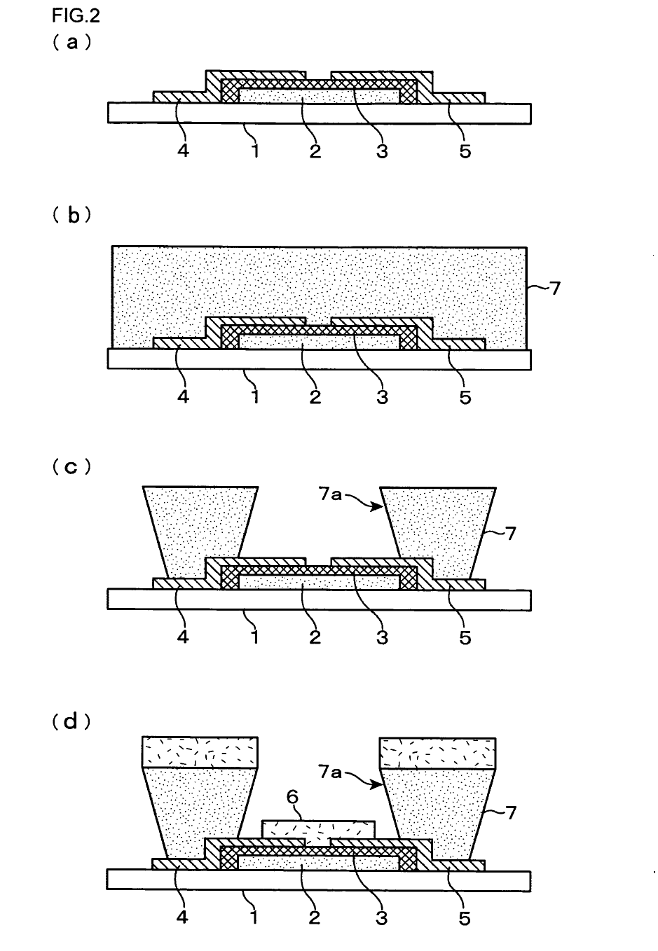

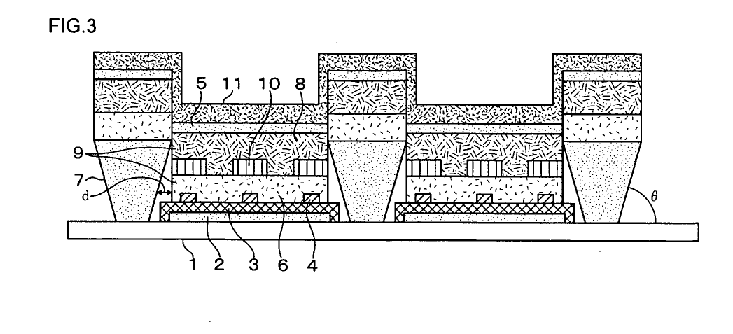

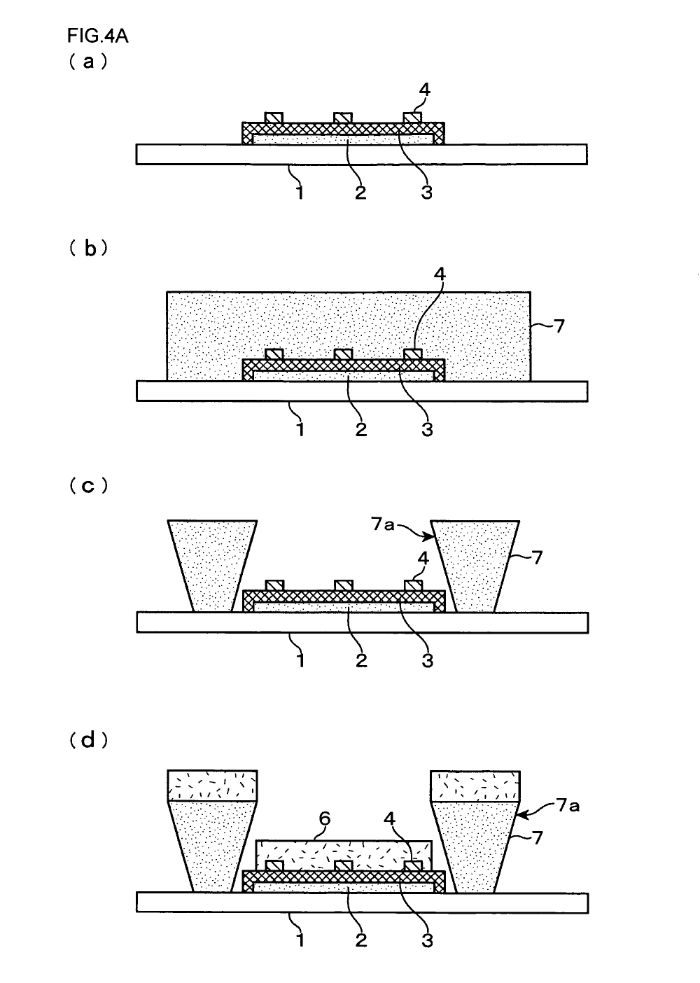

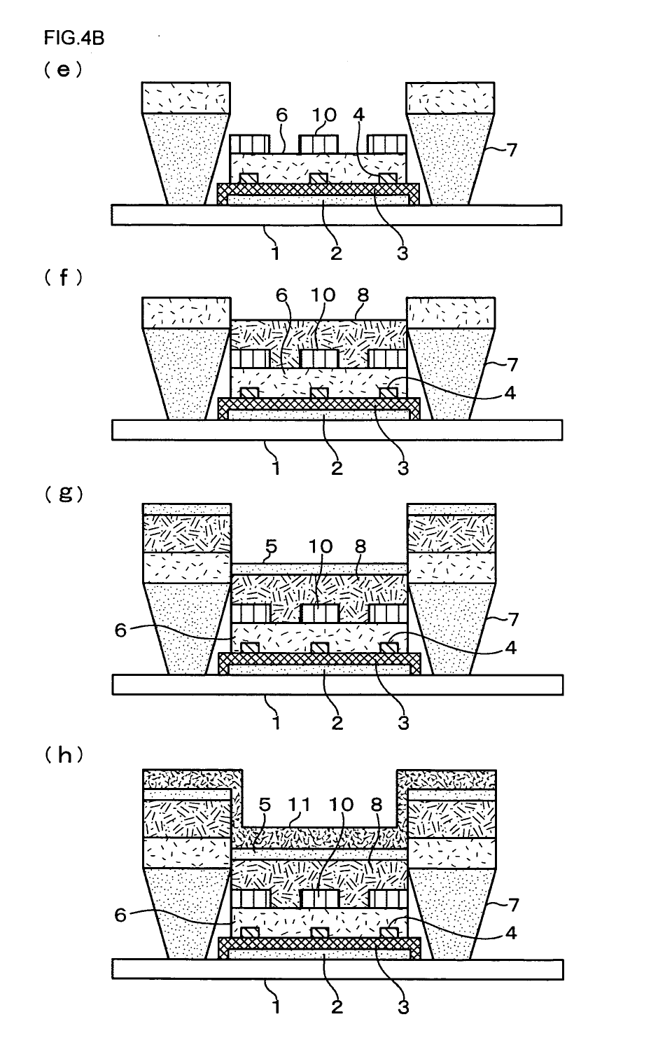

### BRIEF DESCRIPTION OF DRAWINGS

[FIG. 1] FIG. 1 shows schematic diagrams showing an organic TFT which is an embodiment of the present invention, in which FIG. 1(a) is a section view and FIG. 1(b) is a top view.

[FIG. 2] FIGS. 2(a) to 2(d) are diagrams for explaining a method of manufacturing the organic TFT shown in FIG. 1.

[FIG. 3] FIG. 3 is a section view schematically showing an organic light emitting transistor which is another embodiment of the present invention.

[FIG. 4A] FIGS. 4A(a) to 4A(d) are diagrams for explaining a method of manufacturing the organic light emitting transistor shown in FIG. 3.

[FIG. 4B] FIGS. 4B(e) to 4B(h) are diagrams for explaining the method of manufacturing the organic light emitting transistor shown in FIG. 3.

### DESCRIPTION OF REFERENCE NUMERALS

1 SUBSTRATE

2 GATE ELECTRODE

3 GATE INSULATING LAYER

4 SOURCE ELECTRODE

5 DRAIN ELECTRODE

6 ORGANIC SEMICONDUCTOR LAYER

7 INSULATING LAYER

7a OPENING PORTION

8 ORGANIC EL LAYER

9 ORGANIC FUNCTIONAL LAYER

10 CHARGE PREVENTION LAYER

11 ELECTRICAL CONTINUITY LAYER

### BEST MODE FOR CARRYING OUT THE INVENTION

Preferred embodiments of the present invention will hereinafter be described with reference to the drawings. The present invention is not limited to the illustration in the following description.

FIG. 1 shows schematic diagrams showing an organic TFT of a bottom contact type which is an embodiment of an organic transistor according to the present invention. FIG. 1(a) is a section view and FIG. 1(b) is a top view.

The organic TFT shown in FIG. 1 has a substrate 1, a gate electrode 2 formed on the substrate 1, a gate insulating layer formed on the gate electrode 2, a source electrode 4 and a drain electrode 5 formed on the gate insulating layer 3, and an organic semiconductor layer 6 provided between the source electrode 2 and the drain electrode 3 and opposite to the gate electrode 2 with the gate insulating layer 3 interposed between them and made of an organic semiconductor material such as pentacen.

An insulating layer 7 is formed on the source and drain electrodes 4 and 5 on which the organic semiconductor layer 6 is formed. The insulating layer 7 includes an opening portion 7a opened to provide the area where the organic semiconductor layer 6 is formed. The opening portion 7a has an inversely tapered shape on its sides. In forming the organic semiconductor layer 6 with an evaporation method in such a structure, the insulating layer 7 serves as a mask to cause the organic semiconductor layer 6 to be deposited and patterned in a bottom-surface portion of the opening portion 7a. The width of the opening portion 7a adjusts the area where the organic semiconductor layer 6 is formed. The organic semiconductor layer 6 deposited in a top-surface portion of the insulating layer 7 is preferably separated from the organic semiconductor layer 6 in the bottom-surface portion by the height difference between the latter organic semiconductor layer 6 and the insulating layer 7 and is not involved in the operation of the organic TFT. Since the insulating layer 7 has the inversely tapered shape, the organic semiconductor layer 6 in the bottom-surface portion can be separated more reliably. If the opening portion 7a has a vertical shape or a normally tapered shape on its sides, the organic semiconductor layer 6 may adhere to that side to bring the organic semiconductor layer 6 deposited in the top-surface portion of the insulating layer 7 into contact with the organic semiconductor layer 6 deposited in the bottom-surface portion. The inversely tapered shape can prevent the adherence to the side of the insulating layer 7, so that the organic semiconductor layer 6 in the bottom-surface portion can be separated more reliably. Since a gap d is produced between the organic semiconductor layer 6 in the bottom-surface portion of the opening portion 7a and the side of the insulating layer 7, that portion can prevent the contact to attain more reliable separation of the organic semiconductor layer 6. The inversely tapered shape of the insulating layer 7 also allows a reduction in the height of the insulating layer 7.

The opening portion 7a of the insulating layer 7 is preferably wider than the distance between the source and drain electrodes 4 and 5. If the width of opening portion 7a is equal to the distance between the source and drain electrodes 4 and 5, and the organic semiconductor layer 6 is formed from above the insulating layer 7, the deposited organic semiconductor layer 6 may be so thin at an edge portion of the source and drain electrodes 4 and 5 that favorable contact may not be maintained with the source and drain electrodes 4 and 5. Thus, the opening portion 7a of the insulating layer 7 is wider than the distance between the source and drain electrodes 4 and 5 to form the organic semiconductor layer 6 in an area wider than the distance between the source and drain electrodes 4 and 5 so that the organic semiconductor layer 6 is sufficiently deposited at the edge portion of the electrodes, thereby allowing excellent contact.

The insulating layer 7 preferably surrounds a channel portion, formed by the source and drain electrodes 4 and 5, on four sides thereof. As shown in FIG. 1(b), since the opening portion 7a of the insulating layer 7 opens the channel portion and the insulating layer 7 surrounds the channel portion, the channel portion is surrounded all around by the insulating layer 7. In this manner, the insulating layer 7 is provided not only in a length direction but also in a width direction of the channel portion, so that the periphery of the organic semiconductor layer 6 formed in the channel portion is separated by the inversely tapered shape. Thus, the organic semiconductor layer 6 can be individually patterned for each organic TFT. In a structure in which a plurality of TFTs are placed, a leakage current can be prevented by avoiding contact between the organic semiconductor layers 6 of the adjacent organic TFTs. Embodiment 1 is applicable to a structure in which the insulating layer 7 is placed along the channel portion only in the length direction and opens in the width direction.

An angle θ between the surface over which the insulating layer 7 is formed and the side of the opening portion 7a preferably ranges from 40° to 80°. If the angle is smaller than 40°, the inversely tapered shape is difficult to provide and the area of the insulating layer 7 should be increased. If the angle is larger than 80°, the separation is difficult to achieve for some reasons such as adherence of the organic semiconductor layer 6 to the side of the opening portion 7a. Particularly preferably, the angle θ is 70°.

FIG. 2 shows diagrams for explaining a manufacture method of the organic TFT shown in FIG. 1.

As shown in FIG. 2(a), the gate electrode 2 is formed on the substrate 1, the gate insulating layer 3 is formed on the gate electrode 2, and the source and drain electrodes 4 and 5 are formed to place the channel portion on the gate insulating layer 3. For example, Ta is deposited and pattered through dry etching to provide the gate electrode 2, the surface of Ta is anodized into Ta₂O₅ to form the gate insulating layer 3, and a stacked film of Cr and Au is formed to provide each of the source and drain electrodes 4 and 5.

Next, as shown in FIG. 2(b), the insulating layer 7 is formed on the entire surface over the source and drain electrodes 4 and 5. As shown in FIG. 2(c), the insulating layer 7 is patterned to form the opening portion 7a. For example, a photoresist is applied with a spin coat method or the like onto the entire surface having the source and drain electrodes 4 and 5 formed thereon to provide the insulating layer 7, and patterning is performed through exposure and development is performed to remove the photoresist in the opening portion 7a. When a negative resist is used as the photoresist, the resist is exposed to light toward a diameter direction of the opening portion 7a near the bottom surface thereof due to light scattering during the exposure for the opening portion 7a. In the subsequent removal of the photoresist with a developer, the removed portion is gradually widened in the diameter direction of the opening portion 7a toward the bottom surface thereof, thereby forming the opening portion 7a having the inversely tapered shape on its sides. The angle θ can be adjusted by controlling the intensity or the time of the exposure. When the photoresist is used to form the insulating layer 7 in this manner, the thickness of the insulating layer 7 can be adjusted in a range from 1 μm to 10 μm which corresponds to the range in which the photoresist can be formed through application. The formation method of the insulating layer 7 is not limited thereto, and an insulating layer having a normally tapered shape may be formed on another substrate and be transferred to form an insulating layer having an inversely tapered shape on the source and drain electrodes 4 and 5, although not shown.

Next, the organic semiconductor layer 6 made of the organic semiconductor material such as pentacen is formed from above the insulating layer 7. The insulating layer 7 serves as the mask to cause the organic semiconductor layer 6 to be deposited and patterned in the channel portion in the bottom-surface portion of the opening portion 7a. The area where the organic semiconductor layer 6 is formed is adjusted by the width of the opening portion 7a. The insulating layer 7 having the inversely tapered shape can prevent contact with the organic semiconductor layer 6 in the top-surface portion of the insulating layer 7 to separate the organic semiconductor layer 6 more reliably. Since the opening portion 7a is wider than the distance between the source and drain electrodes 4 and 5, the organic semiconductor layer 6 is sufficiently deposited at the edge portion of the source and drain electrodes 4 and 5 to maintain favorable contact. The low-molecular organic semiconductor material such as pentacen can be evaporated to provide the organic semiconductor layer 6.

When the organic semiconductor layer 6 is formed through evaporation by using the low-molecular organic semiconductor material in such an organic TFT, a shadow mask is not used but the insulating layer 7 is used as the mask to enable high-resolution patterning. Since the opening portion 7a of the insulating layer 7 has the inversely tapered shape on its sides, the organic semiconductor layers 6 can be separated more reliably and formed individually for respective organic TFTs. In a structure in which a plurality of organic TFTs are placed, the insulating layer 7 surrounds the periphery of the channel portion to avoid contact between the adjacent organic semiconductor layers 6 to prevent a leakage current. Since the opening portion 7a of the insulating layer 7 is wider than the distance between the source and drain electrodes 4 and 5, the organic semiconductor layer 6 can be sufficiently deposited at the edge portion of the source and drain electrodes 4 and 5 to maintain excellent contact.

FIG. 3 is a section view schematically showing an organic light emitting transistor which is another embodiment of the organic transistor according to the present invention, in which two elements are separated by an insulating layer. In the following, the same members as those in the example of FIG. 1 are designated with the same reference numerals and description of the same structure is omitted.

The organic light emitting transistor shown in FIG. 3 has a structure which is a combination of a vertical-type organic TFT and an organic EL element. Organic functional layers 9, each including an organic semiconductor layer 6 and an organic EL layer 8 between a source electrode 4 and a drain electrode 5, are stacked vertically. Specifically, the transistor has a substrate 1, a gate electrode 2 formed on the substrate 1, a gate insulating layer 3 formed on the gate electrode 2, the source electrode 4 formed in a line shape on the gate insulating layer 3, the organic semiconductor layer 6 formed on the source electrode 4, a charge prevention layer 10 formed on the organic semiconductor layer 6 in a line shape in association with the source electrode 4 vertically and made of an insulating film such as SiO₂, the organic EL layer 8 formed on the charge prevention layer 10, the drain electrode 5 formed on the organic EL layer 8, and an electrical continuity layer 11 formed on the drain electrode 5 and made of an IZO (Indium Zinc Oxide) film or the like. The drain electrode 5 also functions as a cathode of the organic EL layer 8. The charge prevention layer 10 and the electrical continuity layer 11 may be omitted depending on uses and functions.

An insulating layer 7 includes an opening portion 7a opened to provide the area where the organic functional layer 9 is formed including the organic semiconductor layer 6 and the organic EL layer 8. The opening portion 7a has an inversely tapered shape on its sides. The insulating layer 7 is formed on the substrate 1 around the area where the gate electrode 2, the gate insulating layer 3, and the source electrode 4 are formed. In forming the organic semiconductor layer 6 from above the insulating layer 7, the insulating layer 7 serves as a mask to causes the organic semiconductor layer 6 to be patterned in a bottom-surface portion of the opening portion 7a. The area where the organic semiconductor layer 6 is formed is adjusted by the width of the opening portion 7a. The organic semiconductor layer 6 deposited in a top-surface portion of the insulating layer 7 is preferably not involved in the operation of the elements. Since the insulating layer 7 has the inversely tapered shape, the organic semiconductor layer 6 in the bottom-surface portion can be separated more reliably. If the opening portion 7a has a vertical shape or a normally tapered shape on its sides, the organic semiconductor layer 6 may adhere to that side to bring the organic semiconductor layer 6 in the top-surface portion of the insulating layer 7 into contact with the organic semiconductor layer 6 in bottom-surface portion. The inversely tapered shape can prevent the adherence to the side of the insulating layer 7, so that the organic semiconductor layer 6 in the bottom-surface portion can be separated more reliably. Since a gap d is produced between the organic semiconductor layer 6 in the bottom-surface portion of the opening portion 7a and the side of the insulating layer 7, that portion can prevent contact to attain more reliable separation of the organic semiconductor layer 6. The inversely tapered shape of the insulating layer 7 also allows a reduction in the height of the insulating layer 7.

In forming the organic EL layer 8 after the formation of the charge prevention layer 10 on the organic semiconductor layer 6, the insulating layer 7 serves as a mask to cause the organic EL layer 8 to be patterned in the bottom-surface portion of the opening portion 7a. The organic EL layer 8 deposited in the top-surface portion of the insulating layer 7 is not in contact with the organic EL layer 8 in the opening portion 7a due to the thicknesses of the insulating layer 7 and the organic semiconductor layer 6, thereby achieving individual formation for each element.

The insulating layer 7 preferably surrounds the periphery of the area where the organic functional layer 9 is formed. The insulating layer 7 surrounding the area where the organic functional layer 9 is formed all around in this manner allows the individual formation of the organic functional layer 9 reliably separated for each element. When a plurality of elements are arranged, it is possible to avoid contact between the organic semiconductor layers 6 of the adjacent elements to prevent a leakage current. The organic EL layers 8 of the adjacent elements are also prevented from contact to enhance the light emitting performance. Embodiment 2 is applicable to a structure in which the insulating layer 7 regulates only a predetermined direction of the area where the organic functional layer 9 is formed.

When the drain electrode 5 is formed on the organic EL layer 8 in accordance with the shape of the insulating layer 7, the drain electrode 5 is broken due to the height difference between the top-surface portion of the insulating layer 7 and the bottom-surface portion of the opening portion 7a. However, the electrical continuity layer 11 can be formed on the drain electrode 5 to ensure the electrical continuity between the adjacent elements.

As described above, an angle θ between the surface over which the insulating layer 7 is formed and the side of the opening portion 7a of the insulating layer 7 preferably ranges from 40° to 80°, and particularly, a 70° angle is preferable.

FIGS. 4A and 4B are diagrams for explaining a manufacture method of the organic light emitting transistor shown in FIG. 3.

As shown in FIG. 4A(a), the gate electrode 2 is formed on the substrate 1, the gate insulating layer 3 is formed on the gate electrode 2, and the source electrode 4 is formed in the line shape on the gate insulating layer 3. For example, an IZO (Indium Zinc Oxide) film can be deposited and patterned through wet etching to provide the gate electrode 2, the gate insulating layer 3 can be formed by using a photoresist, and Au can be formed through vapor evaporation to provide the source electrode 4.

Next, as shown in FIG. 4A(b), the insulating layer 7 is formed over the entire surface on which the source electrode 4 is formed. As shown in FIG. 4A(c), the opening portion 7a of the insulating layer 7 is removed with patterning. For example, as described above, the insulating layer 7 can have the inversely tapered shape on the sides of the opening portion through the use of a negative photoresist. Alternatively, a normally tapered shape formed on another substrate may be transferred.

Next, as shown in FIG. 4A(d), in forming the organic semiconductor layer 6 made of an organic semiconductor material such as pentacen from above the insulating layer 7, the insulating layer 7 serves as the mask to cause the organic semiconductor layer 6 to be deposited and patterned in the bottom-surface portion of the opening portion 7a. The area where the organic semiconductor layer 6 is formed is adjusted by the width of the opening portion 7a. The inversely tapered shape of the insulating layer 7 can prevent contact with the organic semiconductor layer 6 in the top-surface portion of the insulating layer 7 to separate the organic semiconductor layer 6 more reliably. The low-molecular organic semiconductor material such as pentacen can be evaporated to provide the organic semiconductor layer 6.

Next, as shown in FIG. 4B(e), the charge prevention layer 10 is formed on the organic semiconductor layer 6 in the line shape in accordance with the source electrode 4 vertically. The charge prevention layer 10 can be deposited and patterned with evaporation.

Then, as shown in FIG. 4B(f), the organic EL layer 8 is formed after the formation of the charge prevention layer 10. The organic EL layer 8 is deposited at different heights in the top-surface portion of the insulating layer 7 and in the bottom-surface portion of the opening portion 7a in accordance with the shape of the insulating layer 7 such that the organic EL layer 8 is individually formed for each element. The organic EL layer 8 can be formed with evaporation.

Next, as shown in FIG. 4A(g), the drain electrode 5 is formed on the organic EL layer 8. The drain electrode 5 is also deposited at different heights in the top-surface portion of the insulating layer 7 and in the bottom-surface portion of the opening portion 7a in accordance with the shape of the insulating layer 7. The drain electrode 5 can be formed with evaporation.

Next, as shown in FIG. 4A(h), the electrical continuity layer 11 made of an IZO film or the like is formed on the drain electrode 5. The electrical continuity layer 11 can be deposited including the side of the step formed by the insulating layer 7 to prevent a break of the drain electrode 5 between the adjacent elements. The electrical continuity layer 11 may be formed with sputtering.

When the organic semiconductor layer 6 is formed with evaporation by using the low-molecular organic semiconductor material in such an organic light emitting transistor, a shadow mask is not used but the insulating layer 7 can be used as the mask to attain high-resolution patterning. Since the opening portion 7a of the insulating layer 7 has the inversely tapered shape on its sides, the organic semiconductor layer 6 can be separated more reliably and formed individually for each element. In a structure in which a plurality of elements are placed, the insulating layer 7 surrounds the periphery of the organic semiconductor layer to avoid contact between the adjacent organic semiconductor layers 6 to prevent a leakage current.

The organic semiconductor layer according to the present invention can be provided by using a low-molecular material which can be deposited with an evaporation method such as vacuum evaporation and OVPD (Organic Vapor Phase Deposition), in addition to pentacen described above. Specifically, it is possible to use a phthalocyanine derivative, a naphthalocyanine derivative, an azo compound derivative, a perylene derivative, an indigo derivative, a quinacridone derivative, a polycyclic quinone derivative such as anthraquinone, a cyanine derivative, a fullerene derivative, or a nitrogen-containing cyclic compound derivative such as indole, carbazole, oxazole, inoxazole, thiazole, imidazole, pyrazole, oxaadiazole, pyrazoline, thiathiazole, and triazole, a hydrazine derivative, a triphenylamine derivative, a triphenylmethane derivative, stilbene, a quinone compound derivative such as anthraquinone diphenoquinone, and a polycyclic aromatic compound derivative such as anthracene, bilene, phenanthrene, and coronene.

The substrate according to the present invention can be provided by using a glass substrate as a transparent substrate, a plastic substrate made of PES (Poly Ether Sulphone) or PC (Polycarbonate), and a cemented substrate formed of glass and plastic. An alkali barrier film or a gas barrier film may coat the surface of the substrate. With the use of a film material for the substrate, the present invention is applicable to a flexible device, for example a flexible display.

The gate electrode according to the present invention is not limited to Ta or IZO described above, and both of an organic material and an inorganic material are effective as long as the material is of low resistance. For example, it is possible to use a metal alone such as Pt, Au, W, Ru, Ir, Al, Sc, Ti, V, Mn, Fe, Co, Ni, Cr, Zn, Ga, Y, Zr, Nb, Mo, Tc, Rh, Pd, Ag, Cd, Ln, Sn, Ta, Re, Os, Tl, Pb, La, Ce, Pr, Nd, Pm, Sm, Eu, Gd, Tb, Dy, Ho, Er, Tm, Yb, and Lu, a compound thereof, or a stack thereof. It is also possible to use a metal oxide such as ITO (Indium Tin Oxide) and IZO, or an organic conductive material including a conjugate polymer compound such as polyaniline, polythiophene, and polypyrrole.

The gate insulating layer according to the present invention is not limited to Ta₂O₅ provided through anodization the photoresist described above, and both of an inorganic material and an organic material are effective as long as the material has insulation to some extent. For example, it is possible to use a metal oxide such as LiOx, LiNx, NaOx, KOx, RbOx, CsOx, BeOx, MgOx, MgNx, CaOx, CaNx, SrOx, BaOx, ScOx, YOx, YNx, LaOx, LaNx, CeOx, PrOx, NdOx, SmOx, EuOx, GdOx, TbOx, DyOx, HoOx, ErOx, TmOx, YbOx, LuOx, TiOx, TiNx, ZrOx, ZrNx, HfOx, HfNx, ThOx, VOx, VNx, NbOx, TaOx, TaNx, CrOx, CrNx, MoOx, MoNx, WOx, WNx, MnOx, ReOx, FeOx, FeNx, RuOx, OsOx, CoOx, RhOx, IrOx, NiOx, PdOx, PtOx, CuOx, CuNx, AgOx, AuOx, ZnOx, CdOx, HgOx, BOx, BNx, AlOx, AlNx, GaOx, GaNx, InOx, TiOx, TiNx, SiNx, GeOx, SnOx, PbOx, POx, PNx, AsOx, SbOx, SeOx, and TeOx, a metal compound oxide such as LiAlO₂, Li₂SiO₃, Li₂TiO₃, Na₂Al₂₂O₃₄, NaFeO₂, Na₄SiO₄, K₂SiO₃, K₂TiO₃, K₂WO₄, Rb₂CrO₄, Cs₂CrO₄, MgAl₂O₄, MgFe₂O₄, MgTiO₃, CaTiO₃, CaWO₄, CaZrO₃, SrFe₁₂O₁₉, SrTiO₃, SrZrO₃, BaAl₂O₄, BaFe₁₂O₁₉, BaTiO₃, Y₃A₁₅O₁₂, Y₃Fe₅O₁₂, LaFeO₃, La₃Fe₅O₁₂, La₂Ti₂O₇, CeSnO₄, CeTiO₄, Sm₃Fe₅O₁₂, EuFeO₃, Eu₃Fe₅O₁₂, GdFeO₃, Gd₃Fe₅O₁₂, DyFeO₃, Dy₃Fe₅O₁₂, HoFeO₃, Ho₃Fe₅O₁₂, ErFeO₃, Er₃Fe₅O₁₂, Tm₃Fe₅O₁₂, LuFeO₃, Lu₃Fe₅O₁₂, NiTiO₃, FeTiO₃, BaZrO₃, LiZrO₃, MgZrO₃, HfTiO₄, NH₄VO₃, AgVO₃, LiVO₃, BaNb₂O₆, NaNbO₃, SrNb₂O₆, KTaO₃, NaTaO₃, SrTa₂O₆, CuCr₂O₄, Ag₂CrO₄, BaCrO₄, K₂MoO₄, Na₂MoO₄, NiMoO₄, BaWO₄, Na₂WO₄, SrWO₄, MnCr₂O₄, MnFe₂O₄, MnTiO₃, MnWO₄, CoFe₂O₄, ZnFe₂O₄, FeWO₄, CoMoO₄, CuTiO₃, CuWO₄, Ag₂MoO₄, Ag₂WO₄, ZnAl₂O₄, ZnMoO₄, ZnWO₄, CdSnO₃, CdTiO₃, CdMoO₄, CdWO₄, NaAlO₂, MgAl₂O₄, SrAl₂O₄, Gd₃Ga₅O₁₂, InFeO₃, MgIn₂O₄, Al₂TiO₅, FeTiO₃, MgTiO₃, Na₂SiO₃, CaSiO₃, ZrSiO₄, K₂GeO₃, Li₂GeO₃, Na₂GeO₃, Bi₂Sn₃O₉, MgSnO₃, SrSnO₃, PbSiO₃, PbMoO₄, PbTiO₃, SnO₂—Sb₂O₃, CuSeO₄, Na₂SeO₃, ZnSeO₃, K₂TeO₃, K₂TeO₄, Na₂TeO₃, and Na₂TeO₄, a sulfide such as FeS, Al₂S₃, MgS, and ZnS, a fluoride such as LiF, MgF₂, and SmF₃, a chrolide such as HgCl, FeCl₂, and CrCl₃, a bromide such as AgBr, CuBr, MnBr₂, an iodide such as PbI₂, CuI, and FeI₂, or a metal oxynitride such as SiAlON. It is possible to use a polymer material such as a polyimide, polyamide, polyester, polyacrylate, epoxy resin, phenole resin, and polyvinylalcohol.

The source electrode and the drain electrode according to the present invention are not limited to the stacked film of Cr and Au described above, Au, or Al used as the drain electrode and doubling as the cathode of the organic EL element, and both of an inorganic material and an organic material are effective as long as the material of low resistance. For example, it is possible to use a metal along such as Pt, W, Ru, Ir, Al, Sc, Ti, V, Mn, Fe, Co, Ni, Zn, Ga, Y, Zr, Nb, Mo, Tc, Rh, Pd, Ag, Cd, Ln, Sn, Ta, Re, Os, Tl, Pb, La, Ce, Pr, Nd, Pm, Sm, Eu, Gd, Ta, Tb, Dy, Ho, Er, Tm, Yb, and Lu, a compound thereof, or a stack thereof. It is also possible to use a metal oxide such as ITO and IZO, or an organic conductive material including a conjugate polymer compound such as polyaniline, polythiophene, and polypyrrole.

The organic transistor according to the present invention is characterized to have, over the substrate, the gate electrode, the gate insulating layer, the source electrode and the drain electrode, and the organic semiconductor layer present between the source electrode and the drain electrode and made of the low-molecular organic semiconductor material, wherein the insulating layer is provided over the surface on which the organic semiconductor layer is formed through evaporation, the insulating layer having the opening portion which defines the area where the organic semiconductor layer is formed.

The method of manufacturing an organic transistor according to the present invention is characterized in that, the organic transistor has, over the substrate, the gate electrode, the gate insulating layer, the source electrode and the drain electrode, and the organic semiconductor layer present between the source electrode and the drain electrode, wherein the insulating layer is provided over the surface on which the organic semiconductor layer is formed, the insulating layer having the opening portion which defines the area where the organic semiconductor layer is formed, and the insulating layer is used as the patterning mask to evaporate the low-molecular organic semiconductor material to form the organic semiconductor layer.

According to the organic transistor and the manufacture method thereof, when the organic semiconductor layer is formed through evaporation by using the low-molecular organic semiconductor material, a shadow mask is not used but the insulating layer is used as the mask to enable high-resolution patterning. In addition, the thickness of the source and drain electrode can be reduced as compared with the conventional case. Furthermore, the inversely tapered shape on the sides of the opening portion of the insulating layer can reduce the influence of the edge effect to form the organic semiconductor layer having a uniform thickness.

### EXAMPLES

Examples of the present invention will hereinafter be described. The present invention is not limited to those Examples.

### Example 1

In Example 1, the organic TFTs of the bottom contact type shown in FIG. 1 were produced and the characteristics thereof were evaluated.

Each of the organic TFTs had a channel length and a channel width of 5 μm and 400 μm, respectively. A glass substrate was used as the substrate 1, and Ta was deposited thereon and patterned as the gate electrode 2. Ta had a thickness of 200 nm and the patterning was performed with a dry etching method. Next, the gate insulating layer 3 made of Ta₂O₅ was formed on the surface of Ta with the anodization method to have a thickness of 150 nm. A stacked film of Cr/Au was formed thereon as the source and drain electrodes 4 and 5 to have thicknesses of 5 nm and 100 nm, respectively. The source and drain electrodes 4 and 5 were patterned by using a lift-off method. Next, a photoresist was applied as the insulating layer 7 onto the entire surface over the source and drain electrodes 4 and 5 and was patterned through exposure to form the opening portion 7a opened to provide the channel portion. A negative resist was used as the photoresist to form the inversely tapered shape on the sides of the opening portion 7a. The insulating layer 7 had a height of approximately 4 μm, and the inversely tapered shape had an angle of approximately 70°. Next, pentacen was deposited as the organic semiconductor layer 6 from above the insulating layer 7 with the vacuum evaporation method to have a thickness of 50 nm, thereby producing the organic TFT. The inversely tapered shape of the insulating layer 7 separated the pentacen, and any leakage current to another organic TFT was not observed. The evaluation of the organic TFT characteristics of the element showed the favorable characteristics of mobility: 0.4 cm²/Vs, threshold voltage: −0.2V, and on/off: 10⁵.

### Example 2

In Example 2, the organic light emitting transistors shown in FIG. 3 were produced and the characteristics thereof were evaluated.

A glass substrate was used as the substrate 1, and an IZO film was deposited on the substrate 1 and patterned as the transparent gate electrode 2. The IZO film had a thickness of 100 nm and the patterning was performed with a wet etching method. Next, a photoresist was formed as the gate insulating layer 3 on the gate electrode 2 to have a thickness of 300 nm. Then, Au was vapor-evaporated as the source electrode 4 to have a thickness of 30 nm. The source electrode 4 was patterned with the wet etching method into the line shape. Next, the insulating layer 7 was patterned to include the opening portion 7a opened to provide the area where the organic functional layer 9 should be formed. A negative photoresist was applied to the entire surface as the insulating layer 7 and was patterned through exposure to provide the opening portion 7 having the inversely tapered shape on its sides. The insulating layer 7 had a height of 2 μm, and the inversely tapered shape had an angle of approximately 7°. Next, pentacen was deposited as the organic semiconductor layer 6 from above the insulating layer 7 with the vacuum evaporation. The organic semiconductor layer 6 had a thickness of 50 nm. An insulating film SiO₂ was deposited and patterned in the line shape as the charge prevention layer 10 on the organic semiconductor layer 6 with mask evaporation to have a thickness of 300 nm. Then, Al was formed as the organic EL layer 8 and the drain electrode (also used as the cathode of the organic EL element) 5 with vapor evaporation. Next, an IZO film was formed as the electrical continuity layer 11 with a sputtering method to compensate for the break of the drain electrode 5 due to the inversely tapered shape of the insulating layer 7, thereby ensuring the electrical continuity to the adjacent pixel. The inversely tapered shape of the insulating layer 7 separated the organic semiconductor layer 6 and the organic EL layer 8, and any leakage current to another element through the organic material was not observed. When an electric current was passed through the element, favorable light emission was recognized.

1. An organic transistor comprising, over a substrate, a gate electrode, a gate insulating layer, a source electrode and a drain electrode, and an organic semiconductor layer present between the source electrode and the drain electrode and made of a low-molecular organic semiconductor material,
wherein an insulating layer is provided over a surface on which the organic semiconductor layer is formed through evaporation, the insulating layer having an opening portion which defines an area where the organic semiconductor layer is formed.

2. The organic transistor according to claim 1, wherein the insulating layer is formed to surround a channel portion on four sides thereof, the channel portion being formed by the source electrode and the drain electrode.

3. The organic transistor according to claim 1, wherein the insulating layer has an inversely tapered shape on its sides of the opening portion.

4. The organic transistor according to claim 1, wherein the gate electrode, the gate insulating layer, the source electrode and the drain electrode, the insulating layer, and the organic semiconductor layer are stacked in order over the substrate, and
wherein the opening portion of the insulating layer is wider than a distance between the source electrode and the drain electrode.

5. The organic transistor according to claim 1, wherein the gate electrode, the gate insulating layer, the source electrode, the insulating layer, an organic functional layer including the organic semiconductor layer and an organic EL layer, and the drain electrode are stacked in order over the substrate, and
wherein the opening portion of the insulating layer is an area where the organic functional layer is formed.

6. The organic transistor according to claim 5, wherein the insulating layer surrounds the periphery of the area where the organic functional layer is formed.

7. The organic transistor according to claim 5, further comprising an electrical continuity layer on the drain electrode.

8. The organic transistor according to claim 1, wherein an angle between the surface over which the insulating layer is formed and the side of the opening portion of the insulating layer ranges from 40° to 80°.

9. A method of manufacturing an organic transistor comprising, over a substrate, a gate electrode, a gate insulating layer, a source electrode and a drain electrode, and an organic semiconductor layer present between the source electrode and the drain electrode,
wherein an insulating layer is provided over a surface on which the organic semiconductor layer is formed, the insulating layer having an opening portion which defines an area where the organic semiconductor layer is formed, and the insulating layer is used as a patterning mask to evaporate a low-molecular organic semiconductor material to form the organic semiconductor layer.

10. The method of manufacturing an organic transistor according to claim 9, wherein the insulating layer is formed to surround a channel portion on four sides thereof, the channel portion being formed by the source electrode and the drain electrode.

11. The method of manufacturing an organic transistor according to claim 9, wherein the insulating layer is formed to have an inversely tapered shape on its sides of the opening portion.

12. The method of manufacturing an organic transistor according to claim 9, comprising:
forming the gate electrode on the substrate;
forming the gate insulating layer on the gate electrode;
forming the source electrode and the drain electrode on the gate insulating layer;
forming the insulating layer on a surface over which the source electrode and the drain electrode are formed, the opening portion of the insulating layer being wider than a distance between the source electrode and the drain electrode; and
forming the organic semiconductor layer from above the insulating layer through evaporation.

13. The method of manufacturing an organic transistor according to claim 9, comprising:
forming the gate electrode on the substrate;
forming the gate insulating layer on the gate electrode;
forming the source electrode on the gate insulating layer;
forming the insulating layer on a surface over which the source electrode is formed;
forming an organic functional layer including the organic semiconductor layer and an organic light emitting layer from above the insulating layer; and
forming the drain electrode on the organic functional layer.

14. The method of manufacturing an organic transistor according to claim 13, wherein the insulating layer is formed to surround the periphery of an area where the organic functional layer is formed.

15. The method of manufacturing an organic transistor according to claim 13, further comprising forming an electrical continuity layer on the drain electrode.

16. The method of manufacturing an organic transistor according to claim 9, wherein the an angle between the surface over which the insulating layer is formed and the side of the opening portion of the insulating layer ranges from 40° to 80°.
